(19) United States
(12) Patent Application Publication
(10) Pub. No.: US 2026/0181879 A1
(43) Pub. Date: Jun. 25, 2026

(54) SEMICONDUCTOR STRUCTURE AND FORMATION METHOD THEREOF

(71) Applicant: Winbond Electronics Corp., Taichung City (TW)

(72) Inventors: Jeng-Yang LIN, Taichung City (TW); Yung-Han CHIU, Taichung City (TW)

(21) Appl. No.: 19/344,822

(22) Filed: Sep. 30, 2025

(30) Foreign Application Priority Data
Dec. 25, 2024 (TW) 113150597

(51) Int. Cl. H10B 12/00

(52) U.S. Cl. CPC H10B 12/50; H10B 12/09; H10B 12/482

(57) ABSTRACT

A semiconductor structure and a formation method thereof are provided. The semiconductor structure includes a substrate, a logic gate structure, a capping layer, an interlayer dielectric layer, a barrier layer, and a first contact. The substrate includes peripheral and array areas. The logic gate structure is disposed in the peripheral area and on the substrate. The capping layer is disposed on the logic gate structure. The interlayer dielectric layer is disposed on the capping layer. The barrier layer includes a first portion located in the peripheral area and a second portion located in the array area. The first portion is disposed on the interlayer dielectric layer and directly above the logic gate structure. The first contact is disposed in the interlayer dielectric layer and is in contact with the substrate. The width of the logic gate structure is smaller than the width of the first portion.

### CROSS REFERENCE TO RELATED APPLICATIONS

This application claims priority of Taiwan patent application No. 113150597, filed on Dec. 25, 2024, the entirety of which is incorporated by reference herein.

### TECHNICAL FIELD

The present disclosure relates to a semiconductor structure and a formation method thereof, and, in particular, to a semiconductor structure including a barrier layer, and a formation method of the semiconductor structure.

### BACKGROUND

As semiconductor structures are miniaturized, the size of memory devices continues to shrink as well, in order to increase integration and improve performance. However, this continued reduction in size often leads to leakage current between adjacent components, damage to previously formed components during the fabrication of subsequent components, insufficient component reliability, insufficient process margins (process window), and other problems that can adversely affect the performance of the semiconductor structures.

### BRIEF SUMMARY

The present disclosure may include a barrier layer, and the barrier layer may include a first portion in a peripheral area and a second portion in an array area. The barrier layer may reduce leakage current between adjacent components, prevent components below the barrier layer from being damaged, improve component reliability, and/or improve the process margin, thereby obtaining an improved semiconductor structure and a formation method thereof.

An embodiment of the present disclosure provides a semiconductor structure. The semiconductor structure includes a substrate, a logic gate structure, a capping layer, an interlayer dielectric layer, a barrier layer, and a first contact. The substrate includes a peripheral area and an array area. The logic gate structure is disposed in the peripheral area and on the substrate. The capping layer is disposed on the logic gate structure. The interlayer dielectric layer is disposed on the capping layer. The barrier layer includes a first portion located in the peripheral area and a second portion located in the array area, wherein the first portion is disposed on the interlayer dielectric layer and directly above the logic gate structure. The first contact is disposed in the interlayer dielectric layer and is in contact with the substrate. Wherein the width of the logic gate structure is smaller than the width of the first portion.

An embodiment of the present disclosure provides a method for forming a semiconductor structure. The formation method includes providing a substrate, wherein the substrate includes a peripheral area and an array area. The formation method includes forming a logic gate structure in the peripheral area and on the substrate; forming a capping layer on the logic gate structure; forming an interlayer dielectric layer on the capping layer; forming a first trench in the interlayer dielectric layer; forming a barrier layer in the first trench; and forming a first contact on the substrate. Wherein the width of the logic gate structure is smaller than the width of the first trench.

### BRIEF DESCRIPTION OF THE DRAWINGS

FIGS. 1A to 15A and FIGS. 1B to 15B respectively show schematic cross-sectional views of semiconductor structures at various stages of a formation method according to some embodiments.

FIGS. 16A and 16B respectively show schematic cross-sectional views of semiconductor structures according to some embodiments.

### DETAILED DESCRIPTION

In the present disclosure, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. Hereinafter, the X-axis direction is the first direction D1 (width direction), the Y-axis direction is the second direction D2, and the Z-axis direction is the third direction D3 (thickness direction). In some embodiments, the schematic cross-sectional views described herein are schematic views of the XZ plane. In some embodiments, the schematic cross-sectional views described herein are schematic cross-sectional views taken along a direction parallel to an extension direction of a word line of the semiconductor structure. In some embodiments, a normal direction of a substrate 100 is the third direction D3.

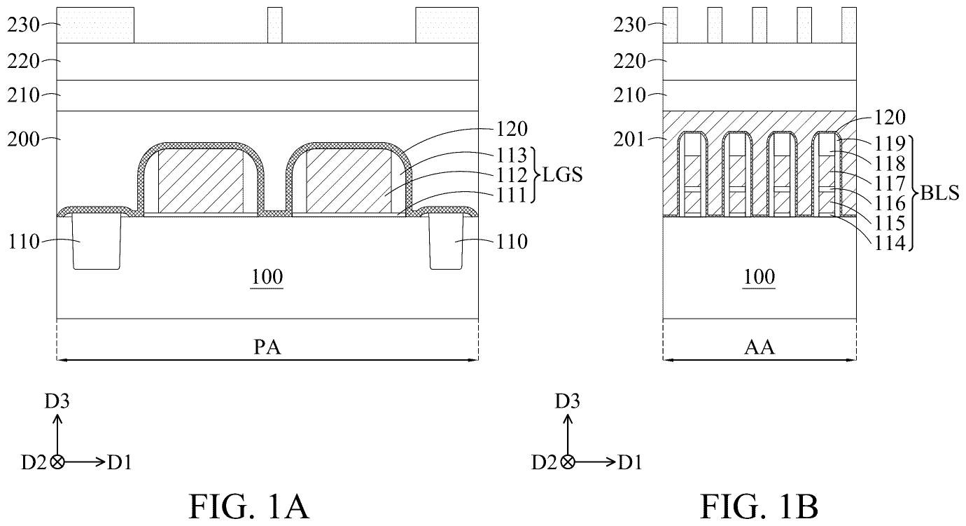

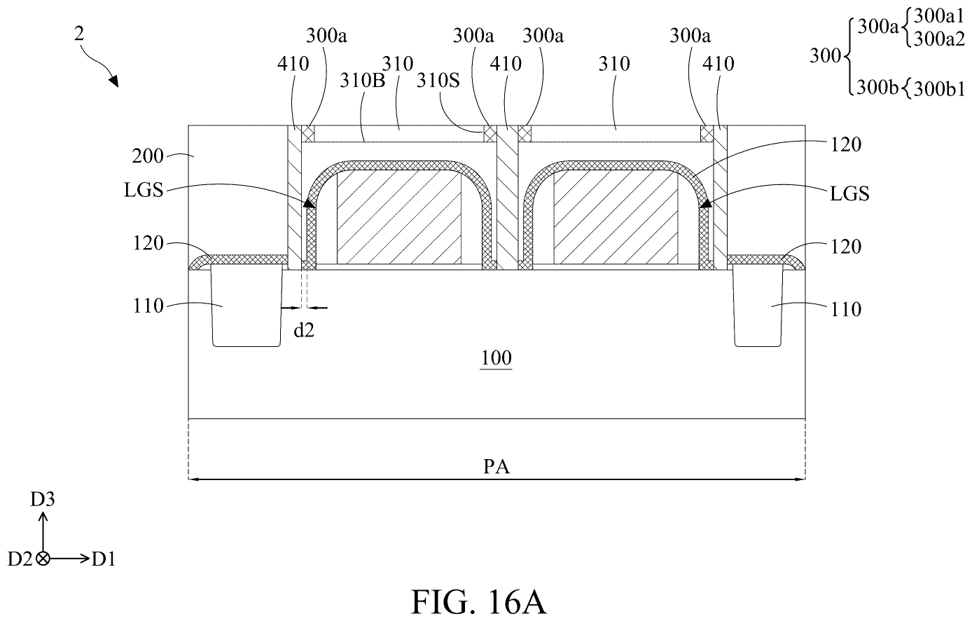

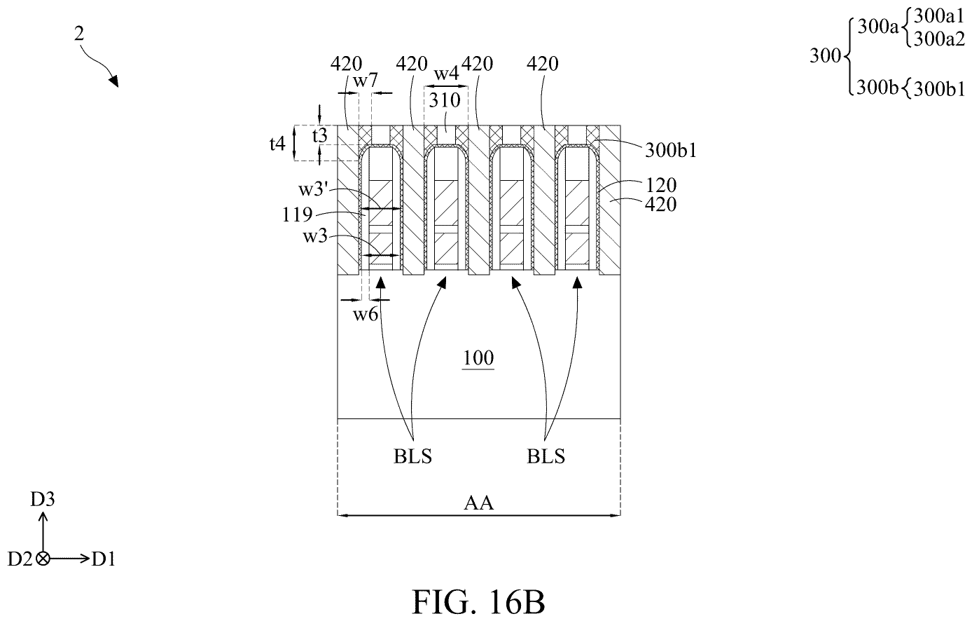

FIG. 1A to FIG. 15A respectively show schematic cross-sectional views of the peripheral area PA of the substrate 100 of the semiconductor structure 1. FIG. 1B to FIG. 15B respectively show schematic cross-sectional views of the array area AA of the substrate 100 of the semiconductor structure 1. FIG. 16A shows a schematic cross-sectional view of the peripheral area PA of the substrate 100 of the semiconductor structure 2. FIG. 16B shows a schematic cross-sectional view of the array area AA of the substrate 100 of the semiconductor structure 2.

Referring to FIG. 1A and FIG. 1B, the substrate 100 may include a silicon wafer, a bulk semiconductor, or a semiconductor-on-insulation (SOI) substrate. Other type of substrate 100 may be, for example, a multi-layer substrate or a gradient substrate. The substrate 100 may include a peripheral area PA and an array area AA, and the peripheral area PA may be disposed adjacent to the array area AA. A memory cell may be disposed in the array area AA, and a peripheral logic circuit for controlling the memory cell may be disposed in the peripheral area PA.

As shown in FIG. 1A, an isolation structure 110 may be formed in a peripheral area PA of a substrate 100 to provide electrical isolation. The isolation structure 110 may include a single-layer or multi-layer structure. For example, the isolation structure 110 may include an oxide such as silicon oxide, a nitride such as silicon nitride, an oxynitride such as silicon oxynitride, another suitable dielectric material, the like, or a combination thereof. In some embodiments, a plurality of trenches (not shown) may be formed in the substrate 100, and the depth, shape, and spacing of the plurality of trenches may be adjusted according to the desired electrical isolation properties. Next, a first dielectric liner (not shown) is conformally formed in the trenches, and then a second dielectric liner (not shown) is conformally formed on the first dielectric liner. Then, a dielectric filler (not shown) is blanketly formed on the second dielectric liner. The isolation structure 110 may be formed by a deposition process such as chemical vapor deposition (CVD).

As shown in FIG. 1A, a logic gate structure LGS may be formed in the peripheral area PA and on the substrate 100. The logic gate structure LGS may include a gate dielectric layer 111, a logic gate 112, and a spacer 113. The gate dielectric layer 111 may be disposed on the substrate 100, the logic gate 112 may be disposed on the gate dielectric layer 111, and the spacer 113 may be disposed on the logic gate 112. In the first direction D1, the spacer 113 may be disposed on opposite sides of the logic gate 112. The gate dielectric layer 111 may include an oxide such as silicon oxide, but the present disclosure is not limited thereto. The gate dielectric layer 111 may include a dielectric material with a high dielectric constant. The logic gate 112 may include polycrystalline silicon; amorphous silicon; metal such as tungsten (W), copper (Cu), silver (Ag), gold (Au), cobalt (Co); metal nitride such as tungsten nitride (WN), titanium nitride (TiN); conductive metal oxide; another suitable material; the like, or a combination thereof. For example, the logic gate 112 may include polycrystalline silicon. The spacer 113 may include a single-layer or a multi-layer structure. For example, the spacer 113 may include an oxide such as silicon oxide, a nitride such as silicon nitride, an oxynitride such as silicon oxynitride, another suitable dielectric material, the like, or a combination thereof, but the present disclosure is not limited thereto. The spacer 113 may include an oxide-nitride-oxide structure or an oxide-nitride-oxide-nitride-oxide structure. The logic gate structure LGS may be formed by a CVD process, a physical vapor deposition process, or a combination thereof.

As shown in FIG. 1A, a capping layer 120 may be conformally formed on the logic gate structure LGS. For example, the capping layer 120 may include an oxide such as silicon oxide, a nitride such as silicon nitride, an oxynitride such as silicon oxynitride, another suitable dielectric material, the like, or a combination thereof. For example, the capping layer 120 may include silicon nitride. The capping layer 120 may be formed by a deposition process such as CVD. In some embodiments, an interlayer dielectric layer 200 may be blanketly formed on the capping layer 120. The material and the formation method of the interlayer dielectric layer 200 may be the same as or different from that of the capping layer 120, but the present disclosure is not limited thereto. For example, the interlayer dielectric layer 200 may include a spin-on-glass (SOG) oxide.

As shown in FIG. 1B, a bit line structure BLS may be formed in the array area AA and on the substrate 100. The bit line structure BLS may include a tunneling dielectric layer 114, a floating gate 115, a dielectric layer 116, a control gate 117, a dielectric layer 118, and a spacer 119. The tunneling dielectric layer 114 may be disposed on the substrate 100, the floating gate 115 may be disposed on the tunneling dielectric layer 114, the dielectric layer 116 may be disposed on the floating gate 115, the control gate 117 may be disposed on the dielectric layer 116, and the dielectric layer 118 may be disposed on the control gate 117. The spacer 119 may be disposed on the control gate 117. The spacer 119 may be disposed on opposite sides of the tunneling dielectric layer 114, the floating gate 115, the dielectric layer 116, the control gate 117, and the dielectric layer 118. The materials and the formation methods of the tunneling dielectric layer 114, the dielectric layer 116, the dielectric layer 118, and the spacer 119 may be the same as or different from that of the capping layer 120. For example, the tunneling dielectric layer 114, the dielectric layer 116, and the dielectric layer 118 may each include silicon oxide, and the spacer 119 may include silicon oxide and silicon nitride. The structure of the spacer 119 may be the same as or different from that of the spacer 113. The materials and the formation methods of the floating gate 115 and the control gate 117 may be the same as or different from that of the logic gate 112, but the present disclosure is not limited thereto. For example, the floating gate 115 and the control gate 117 may each include polysilicon.

As shown in FIG. 1B, a capping layer 120 may be conformally formed on the bit line structure BLS. In some embodiments, a conductive layer 201 may be formed on the capping layer 120. The material and the formation method of the conductive layer 201 may be the same as or different from that of the logic gate 112, but the present disclosure is not limited thereto. For example, the conductive layer 201 may include polysilicon.

As shown in FIG. 1A and FIG. 1B, a mask 210 may be formed on the interlayer dielectric layer 200 and the conductive layer 201, and a mask 220 may be formed on the mask 210. The mask 210 may include silicon nitride, and the mask 220 may include a carbon-based material such as silicon carbonitride. In some embodiments, a photoresist layer 230 may be formed on the mask 220.

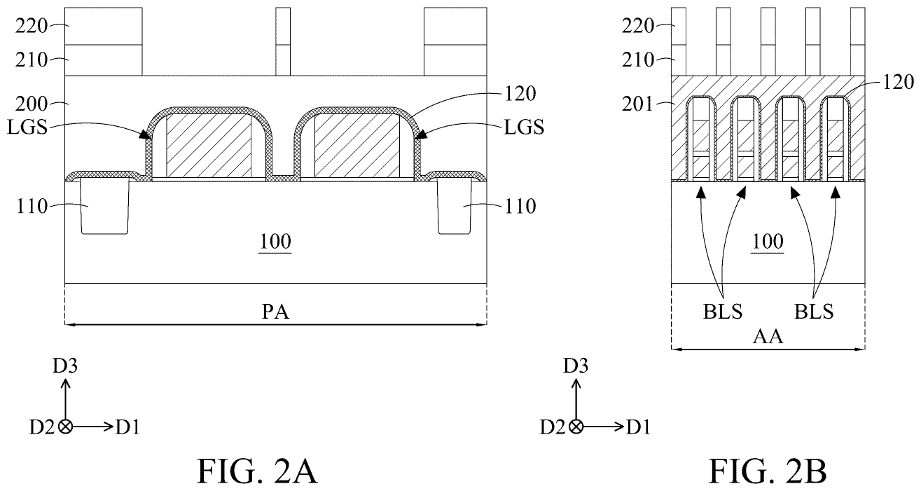

Referring to FIG. 2A and FIG. 2B, the photoresist layer 230 may be used as an etching mask to perform an etching process to pattern the mask 220 and the mask 210. The etching process may include dry etching, wet etching, another suitable removal process, or a combination thereof. For example, the etching process may use a reactive ion etching (RIE) process, but the present disclosure is not limited thereto. Then, a removal process such as an ashing process may be used to remove the photoresist layer 230.

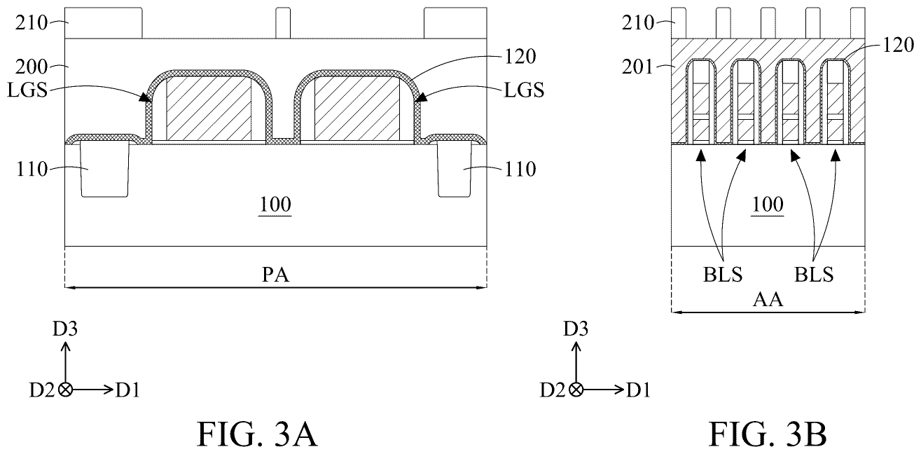

Referring to FIGS. 3A and 3B, the mask 220 may be removed. For example, the mask 220 may be removed by using a cleaning process.

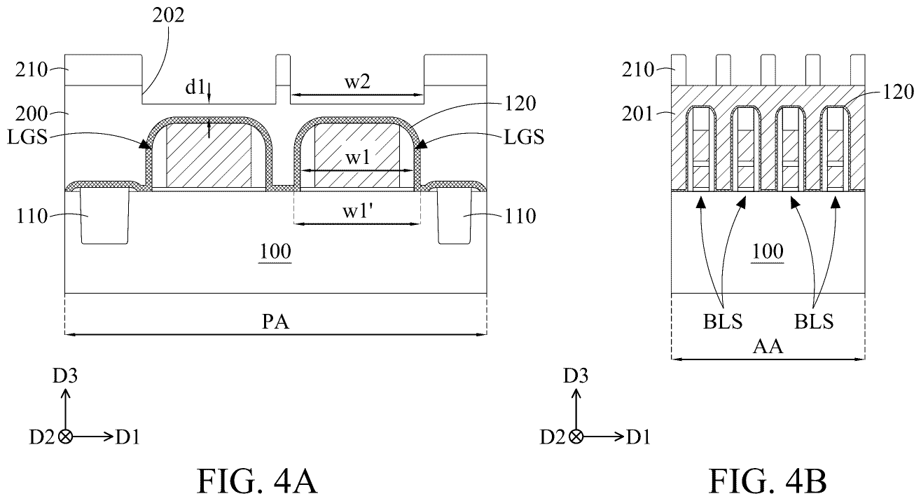

Referring to FIG. 4A and FIG. 4B, the mask 210 may be used as an etching mask to perform an etching process to form a first trench 202 in the interlayer dielectric layer 200. The first trench 202 may be located in the peripheral area PA. Wherein, the etching rate of the etching process for oxide may be greater than that for polysilicon, so that the conductive layer 201 may not be substantially damaged. For example, the etching process may use a reactive ion etching (RIE) process, but the present disclosure is not limited thereto. In some embodiments, the first trench 202 may be located directly above the logic gate structure LGS. The bottom surface of the first trench 202 may be spaced apart from the top surface of the capping layer 120 by a first distance d1 to prevent the first trench 202 from damaging the logic gate structure LGS. In other words, the first trench 202 may not contact the capping layer 120.

As shown in FIG. 4A, in the first direction D1, the logic gate structure LGS may have a first width w1, the first trench 202 may have a second width w2, and the first width w1 of the logic gate structure LGS may be smaller than the second width w2 of the first trench 202. In other words, the projection range of the logic gate structure LGS on the substrate 100 may be within the projection range of the first trench 202 on the substrate 100. In some embodiments, in the first direction D1, the total width w1′ of the logic gate structure LGS and the capping layer 120 may be smaller than or equal to the second width w2 of the first trench 202. Wherein, the total width w1′ may be the maximum total width of the logic gate structure LGS and the capping layer 120 disposed on the logic gate structure LGS in the first direction D1. Accordingly, the width of the barrier layer (for example, the first portion 300a of the barrier layer 300) subsequently formed in the first trench 202 may be greater than the first width w1 of the logic gate structure LGS, and may be greater than or equal to the total width w1′ of the logic gate structure LGS and the capping layer 120. Thus, the barrier layer may serve as a blocking member and/or a mask to protect the logic gate structure LGS located directly below the barrier layer.

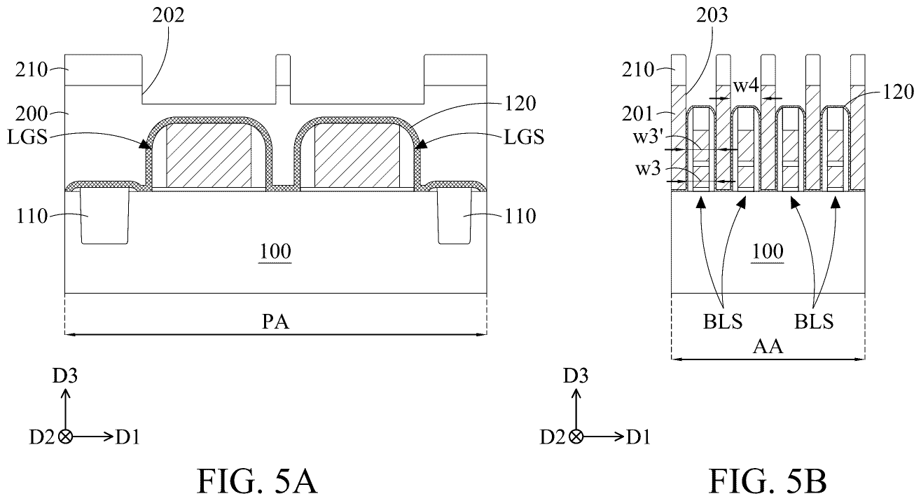

Referring to FIGS. 5A and 5B, the mask 210 may be used as an etching mask to perform an etching process to form a second trench 203 in the conductive layer 201. The second trench 203 may be located in the array area AA. The etching rate of the etching process for oxide may be lower than that for polysilicon, so the interlayer dielectric layer 200 may not be substantially damaged. For example, the etching process may use a reactive ion etching (RIE) process, but the present disclosure is not limited thereto. In some embodiments, the second trench 203 may be located directly above the bit line structure BLS. The second trench 203 may expose the capping layer 120 to avoid damaging the bit line structure BLS.

As shown in FIG. 5B, in the first direction D1, the bit line structure BLS may have a third width w3, the second trench 203 may have a fourth width w4, and the third width w3 of the bit line structure BLS may be smaller than the fourth width w4 of the second trench 203. In other words, the projection range of the bit line structure BLS on the substrate 100 may be within the projection range of the second trench 203 on the substrate 100. In some embodiments, in the first direction D1, the total width w3′ of the bit line structure BLS and the capping layer 120 may be smaller than or equal to the fourth width w4 of the second trench 203. Wherein, the total width w3′ may be the maximum total width of the bit line structure BLS and the capping layer 120 disposed on the bit line structure BLS in the first direction D1. Accordingly, the width of the barrier layer (for example, the second portion 300b of the barrier layer 300) subsequently formed in the second trench 203 may be greater than the third width w3 of the bit line structure BLS, and may be greater than or equal to the total width w3′ of the bit line structure BLS and the capping layer 120. Thus, the barrier layer may serve as a blocking member and/or a mask to protect the bit line structure BLS located directly below the barrier layer.

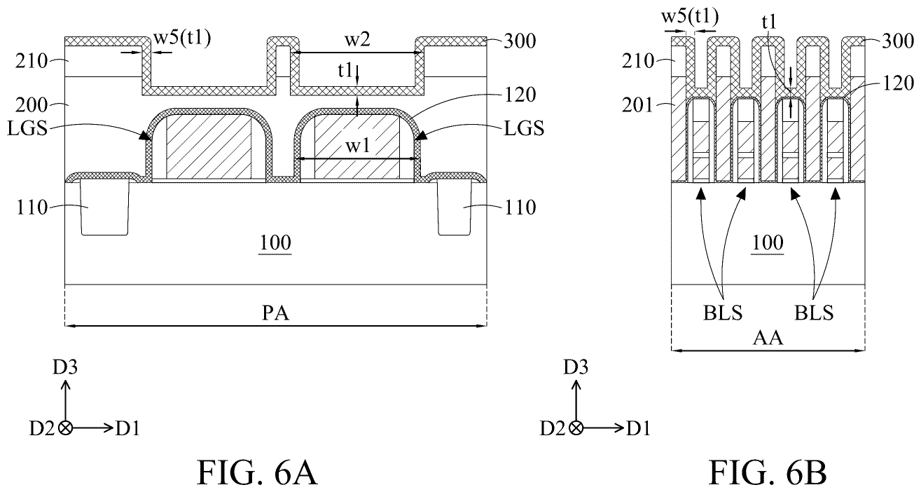

Referring to FIG. 6A and FIG. 6B, the barrier layer 300 may be conformally formed in the first trench 202 and the second trench 203. In the peripheral area PA, the barrier layer 300 may be formed on the mask 210 and the interlayer dielectric layer 200. In the array area AA, the barrier layer 300 may be formed on the mask 210, the conductive layer 201, and the capping layer 120. The material and the formation method of the barrier layer 300 may be the same as or different from that of the capping layer 120, but the present disclosure is not limited thereto. For example, the barrier layer 300 may include silicon nitride. For example, the barrier layer 300 may be formed by a CVD process to improve the quality, reliability, and/or step coverage of the formed barrier layer 300. In some embodiments, in the third direction D3, the barrier layer 300 may have a first thickness t1. In the first direction D1, the barrier layer 300 may have a fifth width w5. Since the barrier layer 300 is conformally formed, the fifth width w5 of the barrier layer 300 may be substantially equal to the first thickness t1 of the barrier layer 300.

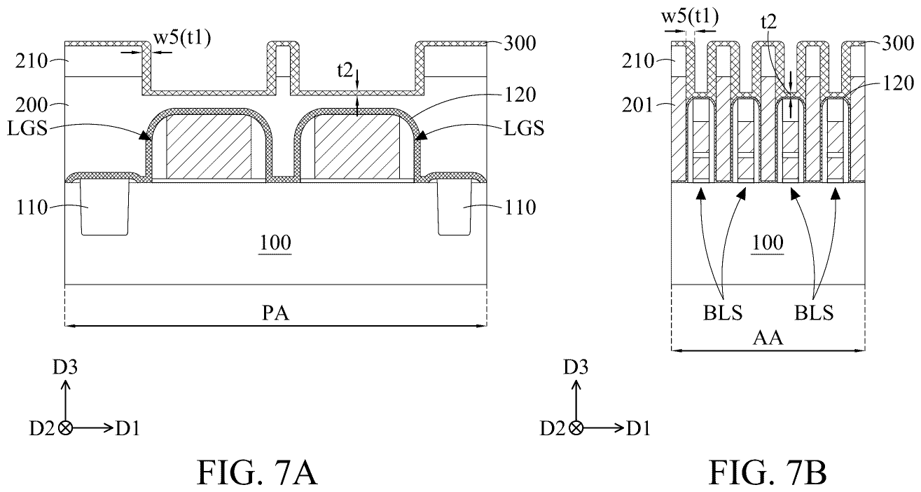

Referring to FIG. 7A and FIG. 7B, the horizontal portion of the barrier layer 300 may be at least partially removed, and the vertical portion of the barrier layer 300 may not be substantially removed. In other words, the horizontal portion of the barrier layer 300 may be thinned, and the fifth width w5 of the vertical portion of the barrier layer 300 may be maintained at a constant value. For example, the removal process may use a reactive ion etching (RIE) process, but the present disclosure is not limited thereto. After the horizontal portion of the barrier layer 300 may be at least partially removed, the horizontal portion of the barrier layer 300 may have a second thickness t2, and the second thickness t2 may be less than the first thickness t1. In some embodiments, the second thickness t2 may be greater than or equal to 0 and less than or equal to 10 nm. For example, the second thickness t2 may be 0, 1 nm, 2 nm, 3 nm, 4 nm, 5 nm, 6 nm, 7 nm, 8 nm, 9 nm, 10 nm, or any value or any range of values between the aforementioned values, but the present disclosure is not limited thereto. In some embodiments, the ratio of the second thickness t2 to the first thickness t1 (the second thickness t2/the first thickness t1) may be 0˜0.4. For example, the ratio of the second thickness t2 to the first thickness t1 may be 0, 0.05, 0.1, 0.15, 0.2, 0.25, 0.3, 0.35, 0.4, or any value or any range of values between the aforementioned values, but the present disclosure is not limited thereto. Accordingly, since the horizontal portion of the barrier layer 300 may be at least partially removed, it may be beneficial to subsequently form a planarization layer (for example, the planarization layer 310) on the barrier layer 300.

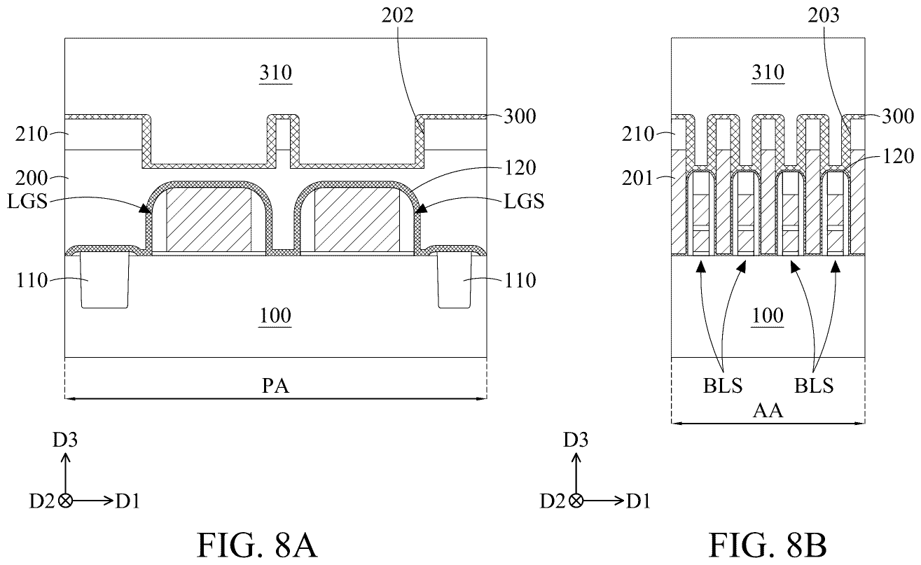

Referring to FIG. 8A and FIG. 8B, a planarization layer 310 may be formed on the barrier layer 300. The planarization layer 310 may be located in the peripheral area PA and the array area AA. The material and the formation method of the planarization layer 310 may be the same as or different from that of the capping layer 120, but the present disclosure is not limited thereto. For example, the planarization layer 310 may include silicon oxide. For example, the planarization layer 310 may include spin-on glass (SOG) oxide to facilitate the planarization layer 310 to be filled into the first trench 202 and the second trench 203.

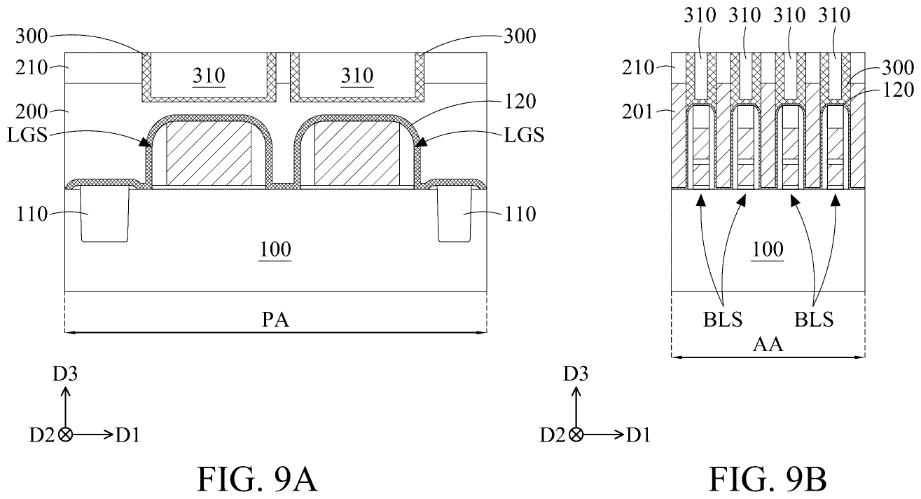

Referring to FIG. 9A and FIG. 9B, a removal process may be performed to make the top surface of the planarization layer 310, the top surface of the barrier layer 300, and the top surface of the mask 210 coplanar. For example, the removal process may use a removal process such as a chemical mechanical polishing (CMP) process, but the present disclosure is not limited thereto.

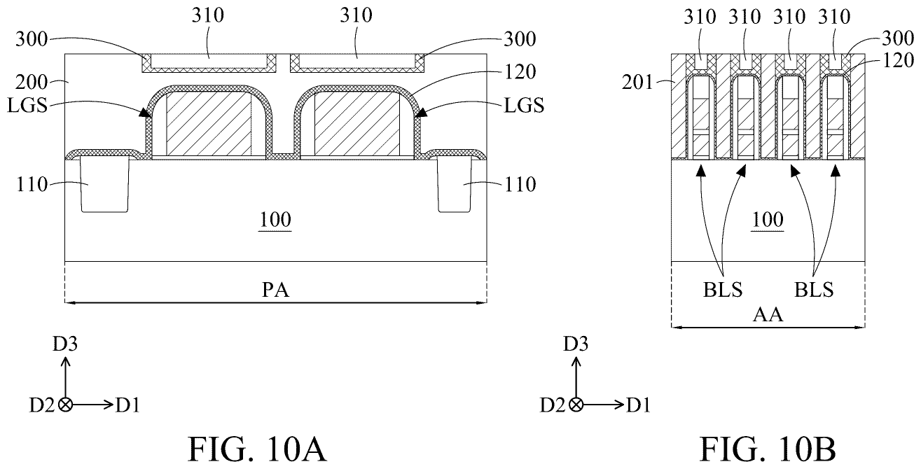

Referring to FIG. 10A and FIG. 10B, an etch-back process may be performed to remove the mask 210. After the etch-back process may be performed, the top surface of the planarization layer 310 and the top surface of the barrier layer 300 may be coplanar.

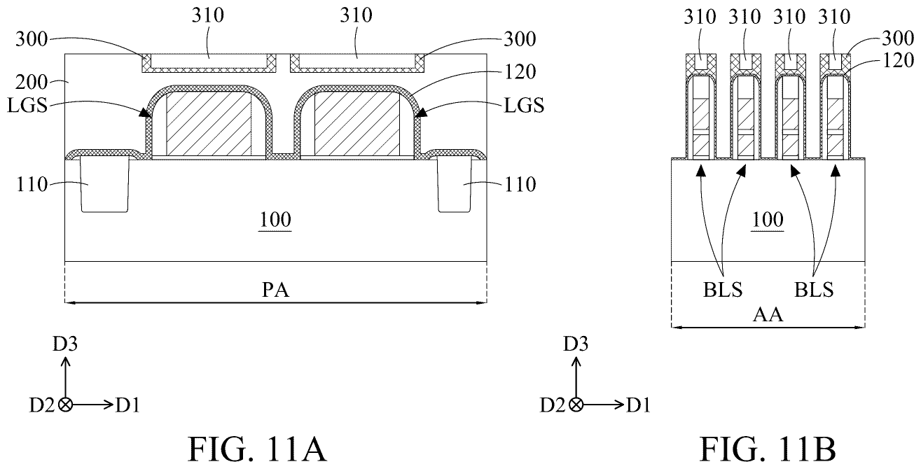

Referring to FIG. 11A and FIG. 11B, the conductive layer 201 in the array area AA may be removed to expose the capping layer 120 in the array area AA.

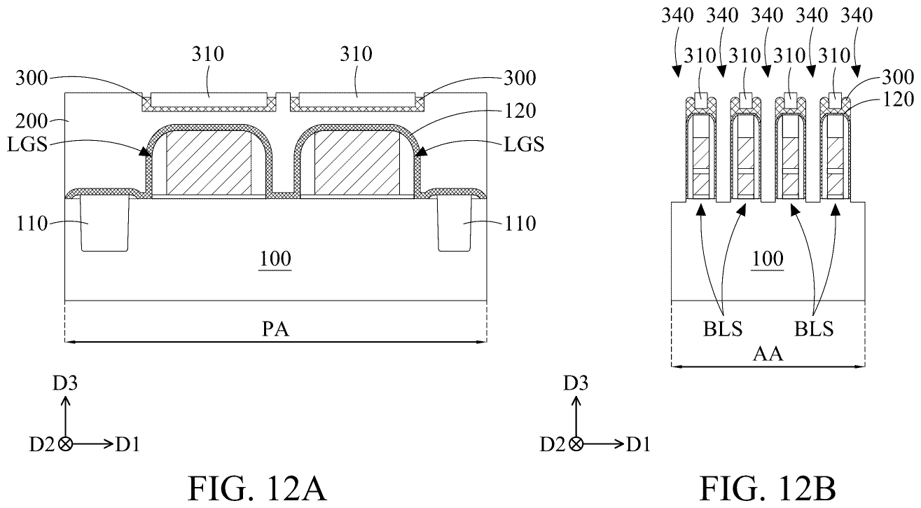

Referring to FIG. 12A and FIG. 12B, the bottom portion of the capping layer 120 in the array area AA may be removed to expose the substrate 100 in the array area AA. Thus, a first opening 340 may be obtained. The first opening 340 may be located between adjacent bit line structures BLS. The first opening 340 may be used to accommodate a contact connected to the memory cell. In some embodiments, during the removal of the bottom portion of the capping layer 120 in the array area AA, a portion of the barrier layer 300 in the peripheral area PA may be removed. Thus, in the peripheral area PA, the top surface of the barrier layer 300 may be lower than that of the planarization layer 310. The first opening 340 may be formed, and then the second opening (for example, the second opening 350) may be formed. Accordingly, during the removal of the conductive layer 201 in the array area AA and the capping layer 120 in the array area AA (to form the first opening 340), since the barrier layer 300 has the blocking and self-alignment effects, the barrier layer 300 may improve the accuracy of forming the opening and/or avoid damaging the bit line structure BLS during the etching process.

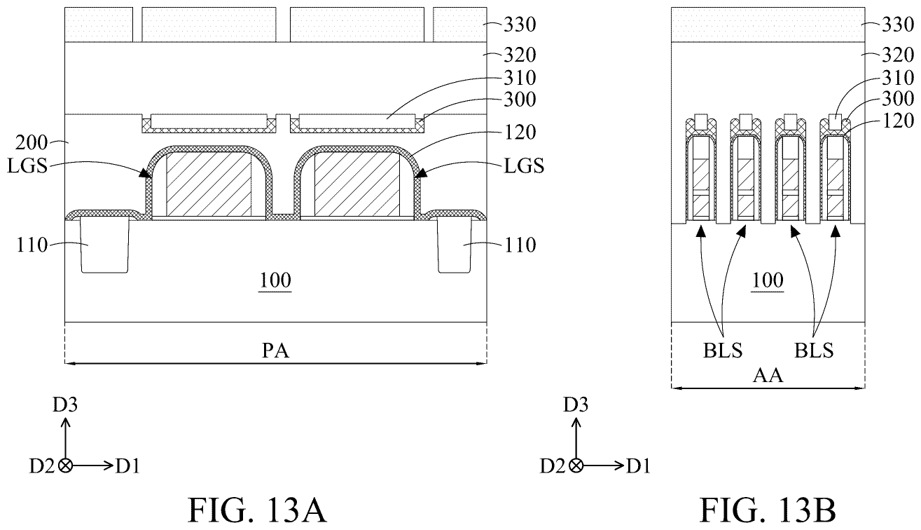

Referring to FIG. 13A and FIG. 13B, a mask 320 may be formed. The mask 320 may be formed on the interlayer dielectric layer 200, the barrier layer 300, and the planarization layer 310. In the array area AA, the mask 320 may be formed on the substrate 100, the capping layer 120, the barrier layer 300, and the planarization layer 310. The mask 320 may include a carbon-based material such as silicon carbonitride. In some embodiments, a photoresist layer 330 may be formed on the mask 320. The photoresist layer 330 may expose the mask 320 in the peripheral area PA and cover the mask 320 in the array area AA. Then, the photoresist layer 330 may be used as etching mask to perform an etching process to pattern the mask 320. The etching process may include dry etching, wet etching, another suitable removal process, or a combination thereof. For example, the etching process may use a reactive ion etching (RIE) process, but the present disclosure is not limited thereto. Next, a removal process such as an ashing process may be used to remove the photoresist layer 330.

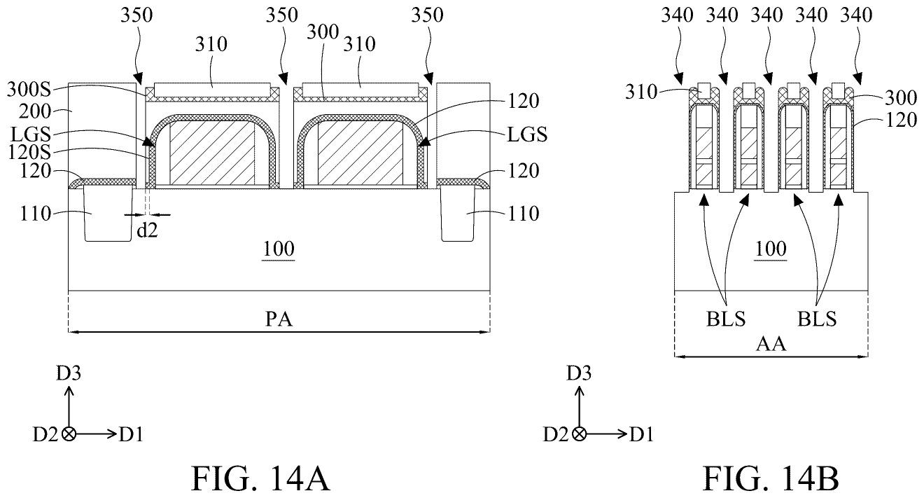

Referring to FIG. 14A and FIG. 14B. In some embodiments, the mask 320 and the barrier layer 300 may be used as etching mask to perform an etching process to form a second opening 350 in the interlayer dielectric layer 200. Then, the mask 320 may be removed. Accordingly, during the removal of the interlayer dielectric layer 200 in the peripheral area PA (to form the second opening 350), the barrier layer 300 has a blocking and self-alignment effects, so the barrier layer 300 may improve the accuracy of forming the opening and/or avoid damaging the logic gate structure LGS in the etching process. It should be noted that although using the mask 320 alone can still define the position of the second opening 350, using the mask 320 and the barrier layer 300 together can further improve the accuracy, reliability and/or process margin of forming the opening. That is, even if there is an mismatch between the pattern of the mask 320 and the desired position of the second opening 350, since the barrier layer 300 has the blocking and self-alignment effects, the barrier layer 300 can more accurately avoid damaging the logic gate structure LGS during the etching process.

As shown in FIG. 14A, the second opening 350 may pass through the interlayer dielectric layer 200 and the capping layer 120 and may expose the substrate 100. The second opening 350 may be used to accommodate a contact connected to the logic gate structure LGS. In some embodiments, in the first direction D1, the side surface 120S of the capping layer 120 may be spaced apart from the second opening 350 by a second distance d2. The second distance d2 may be adjusted according to electrical requirements. For example, the second distance d2 may be greater than or equal to 0. For example, the second distance d2 may be 0, 25 nm, 50 nm, 75 nm, 100 nm, 125 nm, 130 nm, 135 nm, 140 nm, 145 nm, 150 nm, 155 nm, 160 nm, or more. In some embodiments, the mask 320 and the photoresist layer 330 may be removed.

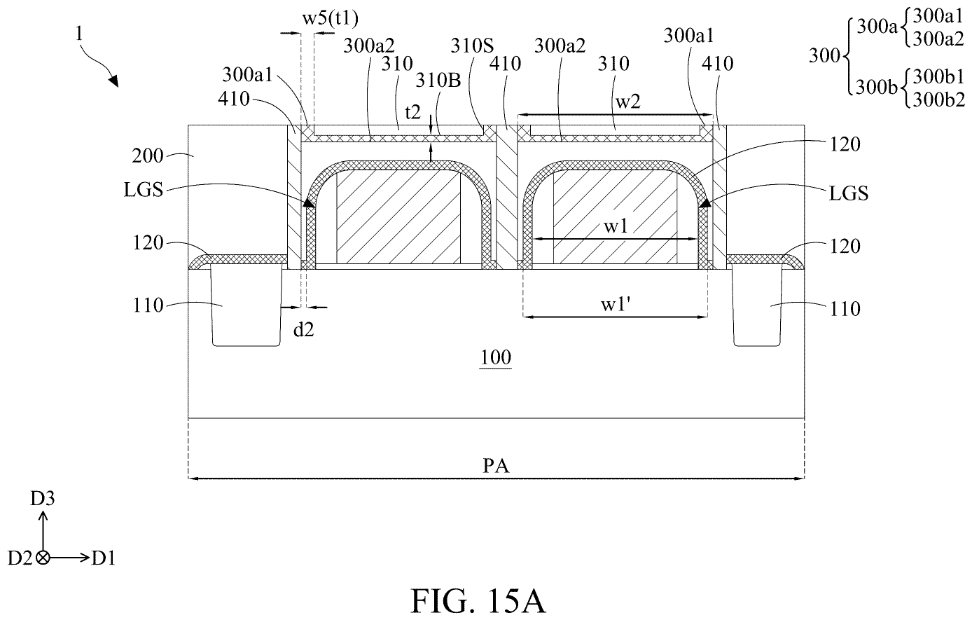

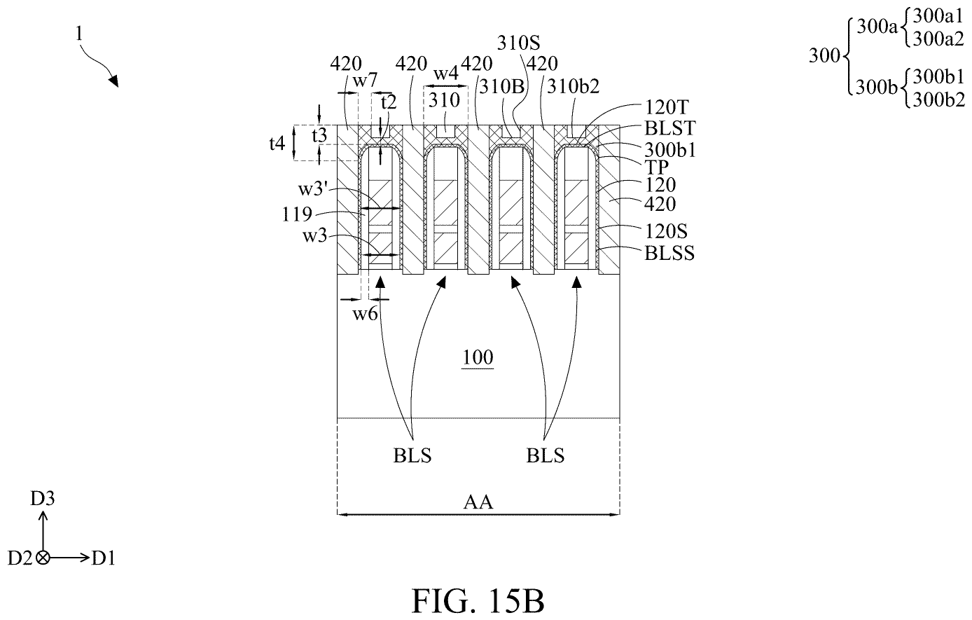

Referring to FIG. 15A and FIG. 15B. In some embodiments, a contact material may be filled in the first opening 340 and the second opening 350 to form a first contact 410 located in the second opening 350 and a second contact 420 located in the first opening 340. The first contact 410 and the second contact 420 may be disposed on the substrate 100. The contact material may be the same as or different from that of the logic gate 112. For example, the first contact 410 and the second contact 420 may each include tungsten.

As shown in FIG. 15A and FIG. 15B, in some embodiments, a removal process may be performed to make the top surface of the interlayer dielectric layer 200, the top surface of the first contact 410, the top surface of the barrier layer 300, and the top surface of the planarization layer 310 in the peripheral area PA coplanar. A removal process may be performed to make the top surface of the second contact 420, the top surface of the barrier layer 300, and the top surface of the planarization layer 310 in the array area AA coplanar. For example, the removal process may use a CMP process. Therefore, a semiconductor structure 1 may be obtained. In some embodiments, the first portion 300a of the barrier layer 300 may cover the side surface 310S and the bottom surface 310B of the planarization layer 310. In some embodiments, the barrier layer 300 may include a first portion 300a and a second portion 300b. The first portion 300a of the barrier layer 300 may be located in the peripheral area PA, and the second portion 300b of the barrier layer 300 may be located in the array area AA.

As shown in FIG. 15A, in some embodiments, in the peripheral area PA, the first portion 300a of the barrier layer 300 may be disposed on the interlayer dielectric layer 200 and may be located directly above the logic gate structure LGS. The first width w1 of the logic gate structure LGS may be smaller than the second width w2 of the first portion 300a of the barrier layer 300. Therefore, when the barrier layer 300 is used as an etching mask to form the second opening 350 for accommodating the first contact 410, the second opening 350 may be prevented from damaging the logic gate structure LGS. Accordingly, leakage current may be prevented from being generated between the logic gate structure LGS and the first contact 410 and/or the logic gate structure LGS may be prevented from being damaged.

As shown in FIG. 15A, in some embodiments, the first contact 410 may be in contact with the first portion 300a of the barrier layer 300. The first contact 410 and the side surface 120S of the capping layer 120 may be spaced apart by a second distance d2. Since the first portion 300a of the barrier layer 300 may be used as a mask to limit the location of the first contact 410, a self-alignment effect may be achieved. In some embodiments, the first portion 300a of the barrier layer 300 may include a first sidewall 300a1 and a first bottom portion 300a2, and the first bottom portion 300a2 may be connected to the first sidewall 300a1. The first sidewall 300a1 may surround the first bottom portion 300a2. In some embodiments, the fifth width w5 of the first sidewall 300a1 may be greater than the second thickness t2 of the first bottom portion 300a2.

As shown in FIG. 15B, in some embodiments, in the array area AA, the second portion 300b of the barrier layer 300 may be disposed on the capping layer 120 and may be located directly above the bit line structure BLS. The third width w3 of the bit line structure BLS may be smaller than the fourth width w4 of the second portion 300b of the barrier layer 300. Therefore, when the first opening 340 for accommodating the second contact 420 is formed, the first opening 340 may be prevented from damaging the bit line structure BLS. Accordingly, leakage current may be prevented from being generated between the bit line structure BLS and the second contact 420 and/or the bit line structure BLS may be prevented from being damaged.

As shown in FIG. 15B, in some embodiments, the second contact 420 may be adjacent to the second portion 300b of the barrier layer 300. The second contact 420 may be in contact with the second portion 300b of the barrier layer 300. Since the second portion 300b of the barrier layer 300 may be used as a mask to limit the location of the second contact 420, a similar self-alignment effect may be achieved. In some embodiments, the second portion 300b of the barrier layer 300 may include a second sidewall 300b1 and a second bottom portion 300b2, and the second bottom portion 300b2 may be connected to the second sidewall 300b1. The second sidewall 300b1 may surround the second bottom portion 300b2. In some embodiments, the seventh width w7 of the second sidewall 300b1 may be greater than the second thickness t2 of the second bottom portion 300b2. In some embodiments, the seventh width w7 of the second sidewall 300b1 may be greater than the sixth width w6 of the spacer 119 of the bit line structure BLS to effectively protect the bit line structure BLS. In some embodiments, the seventh width w7 of the second sidewall 300b 1 may be at least 1.3 times the sixth width w6 of the spacer 119 of the bit line structure BLS. For example, the ratio of the seventh width w7 to the sixth width w6 (the seventh width w7/the sixth width w6) may be 1.3, 1.4, 1.5, 1.6, or more, or any value or any range of values between the aforementioned values, but the present disclosure is not limited thereto. In some embodiments, the second sidewall 300b1 may have a thickness that gradually increases along a direction away from the second bottom portion 300b2, for example, from the third thickness t3 to the fourth thickness t4.

As shown in FIG. 15B, in some embodiments, the second bottom portion 300b of the barrier layer 300 may include a tip portion TP, and the tip portion TP may cover the top surface BLST and the side surface BLSS of the bit line structure BLS. In other words, the tip portion TP may cover the top corner of the bit line structure BLS. Since the top corner of the bit line structure BLS is the first location to be exposed to any energy beam or etchant, the top corner of the bit line structure BLS is most susceptible to damage. Accordingly, the tip portion TP of the barrier layer 300 may protect the bit line structure BLS.

Referring to FIG. 16A and FIG. 16B, when the second thickness t2 as shown in FIG. 7A and FIG. 7B is 0, a semiconductor structure 2 can be obtained. In some embodiments, the first portion 300a of the barrier layer 300 may cover the side surface 310S of the planarization layer 310, and the bottom surface 310B of the planarization layer 310 may be in contact with the interlayer dielectric layer 200.

In some embodiments, the semiconductor structures 1 and/or 2 may be used as a memory device such as a DRAM, or may form a memory device such as a DRAM after further processing is performed on the semiconductor structures 1 and/or 2.

In summary, the semiconductor structure disclosed herein may be provided with a barrier layer, and the barrier layer includes a first portion provided above the logic gate structure in the peripheral area and a second portion provided above the bit line structure in the array area. For example, the first portion of the barrier layer may prevent leakage current from being generated between the logic gate structure and the first contact and/or prevent the logic gate structure from being damaged. For example, the second portion of the barrier layer may prevent leakage current from being generated between the bit line structure and the second contact and/or prevent the bit line structure from being damaged. Accordingly, the reliability of the semiconductor structure may be improved.

Furthermore, in the method for forming the semiconductor structure disclosed herein, since the first portion and the second portion of the barrier layer may be used as masks to limit the location of the first contact and the second contact, respectively, a similar self-alignment effect may be achieved. Therefore, the barrier layer may prevent the other components from being damaged during the process of forming the first contact and/or the second contact. In addition, the first portion and the second portion of the barrier layer may be formed at the same time to simplify the process steps. Accordingly, the process margin of the formation method may be improved.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate comprising a peripheral area and an array area;
a logic gate structure disposed in the peripheral area and on the substrate;
a capping layer disposed on the logic gate structure;
an interlayer dielectric layer disposed on the capping layer;
a barrier layer comprising a first portion located in the peripheral area and a second portion located in the array area, wherein the first portion is disposed on the interlayer dielectric layer and directly above the logic gate structure; and
a first contact disposed in the interlayer dielectric layer and being in contact with the substrate,
wherein a width of the logic gate structure is smaller than a width of the first portion.

2. The semiconductor structure as claimed in claim 1, wherein the first contact is in contact with the first portion.

3. The semiconductor structure as claimed in claim 1, wherein the first contact is spaced a distance from a side surface of the capping layer.

4. The semiconductor structure as claimed in claim 1, wherein:
the first portion further comprises:
a first sidewall; and
a first bottom portion connected to the first sidewall,
wherein a width of the first sidewall is greater than a thickness of the first bottom portion.

5. The semiconductor structure as claimed in claim 1, further comprising:
a planarization layer disposed on the first portion,
wherein the first portion covers a side surface and a bottom surface of the planarization layer.

6. The semiconductor structure as claimed in claim 1, further comprising:
a planarization layer disposed on the first portion,
wherein the first portion covers a side surface of the planarization layer, and a bottom surface of the planarization layer is in contact with the interlayer dielectric layer.

7. The semiconductor structure as claimed in claim 1, further comprising:
a bit line structure disposed in the array area and disposed on the substrate,
wherein the capping layer is disposed on the bit line structure, and the second portion is disposed on the capping layer and is located directly above the bit line structure.

8. The semiconductor structure as claimed in claim 7, wherein a width of the bit line structure is smaller than a width of the second portion.

9. The semiconductor structure as claimed in claim 7, wherein:
the second portion further comprises:
a second sidewall; and
a second bottom portion connected to the second sidewall,
wherein a width of the second sidewall is greater than a width of a spacer of the bit line structure.

10. The semiconductor structure as claimed in claim 9, wherein the width of the second sidewall is at least 1.3 times the width of the spacer of the bit line structure.

11. The semiconductor structure as claimed in claim 9, wherein the second sidewall has a thickness, and the thickness gradually increases in a direction away from the second bottom portion.

12. The semiconductor structure as claimed in claim 7, wherein the second portion comprises a tip portion, and the tip portion covers a top surface and a side surface of the bit line structure.

13. The semiconductor structure as claimed in claim 7, further comprising:
a second contact adjacent to the second portion and being in contact with the substrate.

14. The semiconductor structure as claimed in claim 13, wherein the second contact is in contact with the second portion.

15. The semiconductor structure as claimed in claim 1, wherein the barrier layer comprises silicon nitride.

16. A method for forming a semiconductor structure, comprising:
providing a substrate, wherein the substrate comprises a peripheral area and an array area;
forming a logic gate structure in the peripheral area and on the substrate;
forming a capping layer on the logic gate structure;
forming an interlayer dielectric layer on the capping layer;
forming a first trench in the interlayer dielectric layer;
forming a barrier layer in the first trench; and
forming a first contact on the substrate, wherein a width of the logic gate structure is smaller than a width of the first trench.

17. The formation method as claimed in claim 16, wherein the formation of the first contact on the substrate further comprises:
forming an opening by using the barrier layer as a mask; and
filling a contact material in the opening to form the first contact.

18. The formation method as claimed in claim 16, further comprising:
forming a bit line structure in the array area and on the substrate;
forming the capping layer on the bit line structure;
forming a conductive layer on the capping layer;
forming a second trench in the conductive layer;
forming the barrier layer in the second trench; and
forming a second contact on the substrate;
wherein a width of the bit line structure is smaller than a width of the second trench.

19. The formation method as claimed in claim 16, further comprising:
at least partially removing a horizontal portion of the barrier layer.

20. The formation method as claimed in claim 16, further comprising:
forming a planarization layer on the barrier layer; and
performing a removal process to make the planarization layer coplanar with the barrier layer.
